(19) United States
(12) Patent Application Publication
(10) Pub. No.: US 2026/0269754 A1
(43) Pub. Date: Sep. 10, 2026

(54) CONTINUOUS TESTING OF ANISOTROPY IN SENSORLESS OPERATION OF AN ELECTRICAL MACHINE, FOR THE PURPOSE OF INCREASING RELIABILITY

(71) Applicant: Schaeffler Technologies AG & Co. KG, Herzogenaurach (DE)

(72) Inventor: Erhard Hodrus, Achern (DE)

(21) Appl. No.: 19/166,379

(22) PCT Filed: Feb. 12, 2024
(86) PCT No.: PCT/DE2024/100117

§ 371 Date: Sep. 17, 2025

(30) Foreign Application Priority Data
Mar. 17, 2023 (DE) 10 2023 106 725.7

(51) Int. Cl. H02P 21/18; G01R 31/34

(52) U.S. Cl. CPC H02P 21/18; G01R 31/343; H02P 2207/05

(57) ABSTRACT

A method for continuous anisotropy testing of an electric machine is disclosed. The method includes providing an electric machine having a stationary rotor. The method further includes executing a first application for determining the angle of a longer semi-axis of an ellipse using a first injection signal and executing a second application for determining the angle of a shorter semi-axis of the ellipse using a second injection signal. The method further includes determining the angle difference between the longer semi-axis and the shorter semi-axis. When the angle difference between the longer semi-axis and the shorter semi-axis is within a defined interval between 0 and a defined error tolerance value, the method energizes the electric machine and terminates the process. When the difference in the lengths between a first alternating current vector and a second alternating current vector is greater than a defined tolerance level, the method performs a mitigation procedure.

### CROSS-REFERENCE TO RELATED APPLICATION

The present application is the U.S. National Phase of PCT Patent Application Number PCT/DE2024/100117, filed on Feb. 12, 2024, which claims priority to German Patent Application Number 10 2023 106 725.7, filed Mar. 17, 2023, the entire disclosures of which are incorporated by reference herein.

### TECHNICAL FIELD

The disclosure relates to a method for continuous anisotropy testing of an electric machine, such as a permanent magnet synchronous machine (PMSM), i.e., an electric synchronous machine. The disclosure further relates to a computer program product, a control unit and an electric machine.

### BACKGROUND

When an electric motor is operated without sensors, the rotor position sensor, which is usually used to determine the current angle of the rotor, is omitted. Current sensor signals and measured or estimated phase voltages are used to determine the rotor position and speed of the motor via a model.

Below a rotational speed threshold of the absolute rotational speed, it is necessary to feed in so-called injection signals, which support the identification of the rotor position and the speed in this rotational speed range. Starting with a stationary rotor, the rotor position must be determined by an initialization routine. With the injection methods, the motor can be operated in the lower rotational speed range until, for example, a switch to a model-based sensorless algorithm takes place.

In other words, in sensorless operation, only the current sensors, which are indispensable for field-oriented current regulation in any case, are used. This control concept, which is particularly widespread in three-phase permanent magnet synchronous machines, is based on a transformation of the three-phase alternating variables into a two-axis coordinate system which rotates synchronously with the rotor flux of the machine. In such a coordinate system, commonly referred to as a d/q coordinate system, for example, the three phase currents of the stator winding i_u, i_v, i_w are represented by a 2-dimensional current vector with the components i_q and i_d. For an ideal sinusoidal rotor flux and ideal sinusoidal phase currents, the original alternating variables i_u, i_v, i_w are mapped to equal variables i_q, i_d as a result of the rotor flux-synchronously rotating coordinate system.

In field-oriented current regulation, the voltage values or current values of the phases of the stator of the synchronous machine are transformed in a known manner to a two-dimensional coordinate system, the mutually perpendicular axes of which are usually referred to as d (“direct”) and q (“quadrature”). This coordinate system rotates relative to the stator of the synchronous machine and rests relative to the rotor of the synchronous machine. The transformation itself is referred to as the Park transformation; the two-dimensional coordinate system to which it is transformed is referred to as the Park coordinate system. The Park transformation can occur via the intermediate step of an, also known, Clarke transformation, which transforms the voltage values or current values of the phases of the stator of the synchronous machine to a two-dimensional, orthogonal coordinate system that is stationary relative to the stator.

When an electric motor is operated without sensors, as already mentioned above, the rotor position sensor, which is usually used to determine the current angle of the rotor, is omitted. For example, current sensor signals and measured or estimated phase voltages are used to determine the rotor position and speed of the motor via a model. Below a rotational speed threshold of the absolute rotational speed, it is necessary to feed in so-called injection signals, which support the identification of the rotor position and the speed in this rotational speed range. Starting with a stationary rotor, the rotor position must be determined by an initialization routine.

The initial rotor position can be ascertained by specifying an alternating voltage excitation, a high-frequency oscillation in the d- and q-voltage, for a certain number of points on a voltage circuit path, in which the exciting voltage amplitude leads to a resulting current amplitude. Due to the d-q coordinates, an ellipse in the d-q plane must be formed in the case of a circular excitation in the voltage in the current. In this regard, the main axis of the ellipse corresponds to the d-direction. This direction of the main axis therefore describes the initial value of the rotor position.

One way to determine the initial rotor position is to approach several points on the circular path, which results in several points on an ellipse. From these points the angular position of the semi-axes of the ellipse must then be determined. If one chooses many points, then the result is more accurate, but it takes a certain amount of time since each point must be approached and evaluated in a stable manner with a different amplitude in the d and q directions. If one chooses fewer points, then the process will be faster, but the result may then be inaccurate because the angular position of the semi-axes cannot be determined as well from the few points. The measurement data during evaluation are subject to a certain amount of noise, which ultimately distorts the result. In contrast to buried magnets, the inductances Ld and Lq of bonded magnets are more similar to one another. The ellipse is then not as pronounced and rather resembles a circle.

DE102007003874A1 describes a method for the field-oriented operation of an inverted-fed, sensorless rotating field machine with asymmetries, wherein an estimated flux position is continuously corrected by means of a test signal which is fed into the rotating field machine in the direction of a presumed flux axis. At least two alternating signals of different frequencies are provided as test signals at the same time.

EP2432115A1 also describes a method for continuous anisotropy testing of an electric machine.

### SUMMARY

The object of the disclosure is therefore to provide an improved—in particular faster and more accurate—method for determining an initial rotor position of a rotor of an electric machine, in particular a synchronous electric machine, and thus to test the continuous anisotropy of the electric machine. It is furthermore the object of the disclosure to implement a computer program product for carrying out an improved method for determining an initial rotor position of a rotor of an electric machine, in particular a synchronous electric machine. It is also the object of the disclosure to develop a control unit for carrying out an improved method for determining an initial rotor position of a rotor of an electric machine, in particular a synchronous electric machine. A final object of the disclosure is also to provide an improved electric machine.

This object is achieved by a method for determining an initial rotor position of a rotor of an electric machine, in particular a synchronous electric machine, comprising the following steps:

It is the object of the present disclosure to provide an improved charging system, since the known solutions always have certain disadvantages.

In other words, in sensorless operation, the difference between the inductances in Ld and Lq in the system under consideration should be verified continuously. For this purpose, the angle of the longer semi-axis of the ellipse is determined with an injection signal and the angle of the shorter semi-axis of the ellipse is determined with a second injection signal. It is expected that both semi-axes are situated at right angles to one another. If this is not the case for a longer period of time, minus a tolerance threshold, appropriate conclusions can be drawn, such as shutting down the system.

This object is achieved by a method for determining an initial rotor position of a rotor of an electric machine, in particular a synchronous electric machine, comprising the following steps:
a) providing an electric machine having a stationary rotor,
b) executing a first application for determining the angle w_d_est of a longer semi-axis d of an ellipse using a first injection signal;
c) executing a second application for determining the angle w_q_est of a shorter semi-axis q of the ellipse using a second injection signal;
d) determining the angular difference between the absolute values of the longer semi-axis d and the shorter semi-axis q according to delta_w=|w_d_est−w_q_est|,
e) if the condition is met that the angle difference between the absolute values of the longer semi-axis d and the shorter semi-axis q is within a defined interval between 0 and a defined error tolerance value FTW, according to |delta_w−90|≤FTW, energizing the electric machine and terminating the method,
f) if the condition is met that the difference in the absolute values of the lengths between the first alternating current vector and the second alternating current vector is |delta_w−90|>FTW, outputting of a warning message and/or switching off the system,
g) repeating the steps b) to f).

Advantageously, step b) executing a first application for determining the angle w_d_est of a longer semi-axis d of an ellipse using a first injection signal and c) executing a second application for determining the angle w_q_est of a shorter semi-axis q of the ellipse using a second injection signal are performed in parallel and simultaneously.

Furthermore, the possible 180° uncertainty should be resolved for the operation of the motor based on the longer semi-axis. When resolving the 180° uncertainty, the difference angle between the angle of the d- and q-axis can then be reversed in sign. Such a change should not occur during operation. If it still occurs, it indicates that the ellipse expression is weak, for example.

The two angles for the d- and q-axis found should differ by +/−90°. If the deviation from +/−90° is too great, this should be reported to a superimposed software for diagnostic purposes, e.g., to shut down the system. Possible trigger thresholds must be determined experimentally. In this regard, the trigger thresholds can be determined depending on the current of iq and id in characteristic maps. The trigger thresholds can also be determined depending on the temperature.

During operation, conspicuous operating points can be blocked by means of an adaptive learning algorithm if anomalies occur repeatedly. This could possibly avoid a shut-down of the system and increase availability.

This provides numerous advantages. Methods already known require different inductances in the d and q directions, as only then the ellipse is pronounced. With the method according to the disclosure, the ellipse can always be reliably detected even if it is not as pronounced. This makes it possible to continuously determine the ratio of inductances in the system during operation from the control unit connected later during operation and thus to evaluate the inductances. System-specific influences with respect to the current measurement and the motor parameters are thus taken into account. The motor parameters that initially ensured that the ellipse would be detected correctly may change during operation, e.g. due to demagnetization or ageing of the components, so that the previous detection during commissioning may not appear sufficient under all circumstances. Although the method according to the disclosure cannot reduce these influences, the safer and better reproducible anisotropy testing of the electric machine helps to keep it in operation for as long as possible.

Advantageous embodiments are claimed in the dependent claims and are explained in more detail below.

Advantageously, the first application for determining the angle of the longer semi-axis d according to step b) of the method comprises the following steps:
I) providing a starting value d_est, which represents a first angle of the rotor position,
II) generating a three-phase alternating voltage excitation in the electric machine by specifying an alternating voltage in a d_est direction,
III) converting the three-phase current response to the alternating voltage excitation of the electric machine for the first modified value d_est−45° into a first alternating current component i_[d_est−45°],
IV) converting the three-phase current response to the alternating voltage excitation of the electric machine for the second modified value d_est+45° into a second alternating current component i_[d_est+45°],
V) calculating the length of a first alternating current vector having d and q components for the first alternating current component i_[d_est−45°],
VI) calculating the length of a second alternating current vector having d and q components for the second alternating current component i_[d_est+45°],
VII) determining the difference in the absolute values of the lengths between the first alternating current vector and the second alternating current vector according to delta_i=|i_d_est+45°|−|i_d_est−45°|,
VIII) if the condition is met that the difference in the absolute values of the lengths between the first alternating current vector and the second alternating current vector is within a defined interval between 0 and a defined error tolerance value FTW, according to |delta_i|<FTW, providing the initial rotor angle for energizing the electric machine and terminating the method,
IX) if the condition is met that the difference in the absolute values of the lengths between the first alternating current vector and the second alternating current vector is |delta_i|>FTW,
X) in the case that |i_d_est+45°|>|i_d_est−45°|, adjusting the starting value d_est in such a way that the angle representing the rotor position is rotated clockwise by a predetermined absolute value and
XI) in the case that |i_d_est+45°|<|i_d_est−45°|, adjusting the starting value d_est in such a way that the angle representing the rotor position is rotated counterclockwise by a predetermined absolute value,
   repeating the steps III) to XI).

In other words, a current can be measured by superimposing the injection signal on the voltage. However, this is not transformed into the notional d-direction, but into the notional d−45° direction and notional d+45° direction. This allows for significantly larger amplitudes in the current to be achieved compared to an evaluation of the currents in the d- and q-direction, where the current in the q-direction disappears when the real d-axis is found. This makes detection more robust against disturbances, and especially in dynamic situations. The amplitude of the injection signal is then determined using bandpass filtering and the two values for +−45° are compared. The assumed angle is then corrected so that the two amplitudes in the direction +45° and −45° become equal. The correction is chosen in such a way that the longer semi-axis is found here, i.e., the d-axis. If the sign is reversed during the correction, the algorithm finds the shorter semi-axis, i.e., the q-axis. With this approach, not only can the initial angle be found, but the electric motor can and will be operated with it.

This has the advantage that the initial rotor position can be determined particularly quickly and reliably using an iterative method without a physical rotor position sensor. Furthermore, the method according to the disclosure can also prevent the electric machine from rotating in the wrong direction, even for a short time, during motor operation.

Advantageously, at the beginning of the iterative solution algorithm, the first iteration is carried out with a randomly chosen starting value d_est for the angle. The three-phase current response to an alternating voltage excitation of the system in the supposed d-direction is then converted into d-q-currents using the known methods.

Preferably, the second application for determining the angle of the shorter semi-axis q according to step c) of the method comprises the same steps I) to XII) of the first application, wherein a sign reversals occurs in the angle correction.

Preferably, the frequency of the first injection signal and the frequency of the second injection signal are selected such as to be different. The frequency of the second injection signal must be selected such as to be significantly different from the first injection signal. It should be noted that the bandpass filtering of both injection signals should not show any interference. The frequency should also not be selected too low. Conceivable values for a pump actuator would be f1=4 kHz for the longer semi-axis and f2=3.2 kHz for the shorter semi-axis.

The object of the disclosure can also be achieved by a computer program product stored on a machine-readable medium, or a computer data signal made manifest by an electromagnetic wave, with program code suitable for carrying out the method according to the previously described aspects.

Furthermore, the object of the disclosure can also be achieved by a control unit for controlling and energizing an electric machine, in particular a synchronous electric machine, comprising a processor and a memory containing a computer program code, wherein the memory and the computer program code are configured, with the processor, to cause the control unit to carry out a method for continuous anisotropy testing of an electric machine. According to a further particularly preferred embodiment of the disclosure, the control unit does not have a connection for a rotor position sensor for detecting the rotor position of the rotor so that the control unit or the electric machine controlled by it does not require a physical rotor position sensor.

Finally, the object of the disclosure can also be achieved by an electric machine, in particular a synchronous electric machine, comprising a stator and a rotor rotatable relative to the stator and a control unit for controlling and energizing the electric machine, characterized in that the control unit is a control unit according to the features as described above. In a likewise preferred embodiment of the disclosure, the electric machine does not have a rotor position sensor for detecting the rotor position of the rotor. It can also be advantageous to further develop the disclosure such that the electric machine is configured for use in an electrically operable or hybrid drive train of a motor vehicle or also in a drive train of a pump or a compressor of a production installation.

The disclosure is also explained in more detail below with the aid of drawings.

### BRIEF DESCRIPTION OF THE DRAWINGS

In the drawings:

FIG. 1 shows different positions of the d-axis in a d/q coordinate system,

FIG. 2 shows different positions of the q-axis in a d/q coordinate system,

FIG. 3 shows an electric machine in a schematic representation,

FIG. 4 shows motor vehicles with one hybrid and one fully electrically operable drive train each in a schematic representation.

### DETAILED DESCRIPTION

The figures are only schematic in nature and serve only for understanding of the disclosure. Identical elements are provided with the same reference symbols.

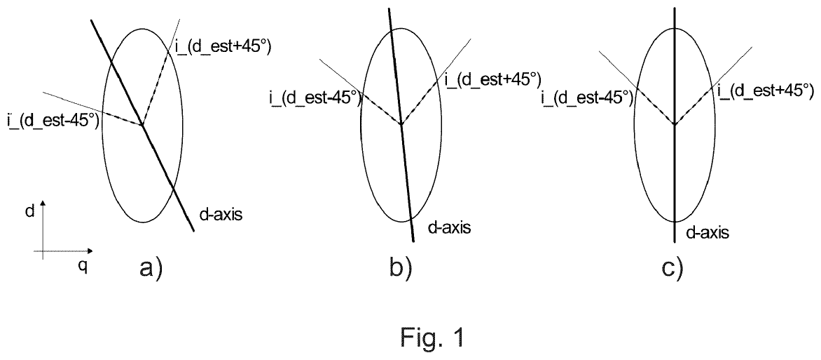

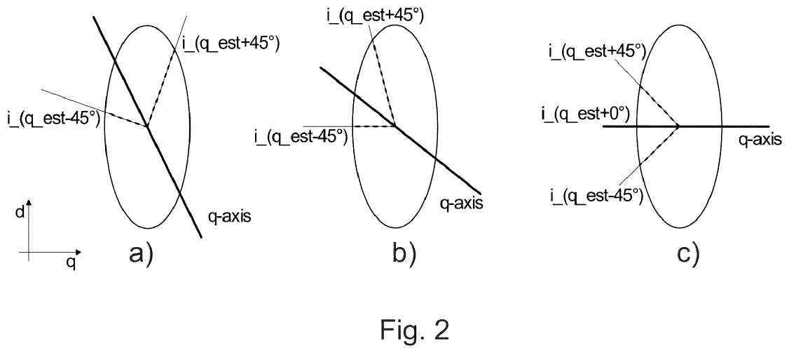

On the basis of FIGS. 1 and 2, the method for continuous anisotropy testing is explained in more detail below. The first application shown in FIG. 1 and the second application shown in FIG. 2 run synchronously and should actually be superimposed in a diagram. For reasons of clarity, such a superimposition has been avoided here.

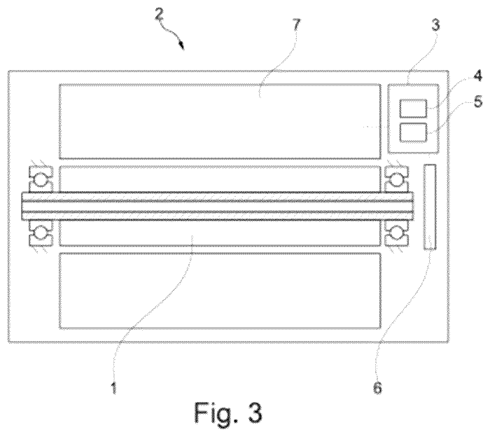

First, an electric machine 2 with a stationary rotor 1 is provided, as shown by way of example in FIG. 3. By means of the control unit 3, in the electric machine 2 a three-phase alternating voltage excitation is then generated in the electric machine 2, which is also indicated in FIG. 3 with the three parallel dashed lines between the control unit 3 and the energized stator 7.

First, the first application and the second application of the method are carried out in parallel. For the sake of simplicity, the steps of the first application are shown first.

First, a random starting value d_est is provided, which represents a first angle of the rotor position. Based on this starting value d_est, the alternating voltage excitation is applied in the d_est direction. The three-phase current is measured and transformed into the d_est−45° direction, and the modified value d_est−45° is calculated. Analogously, a second modified value d_est+45° is calculated, which corresponds to the starting value d_est plus 45°.

Subsequently, a conversion of the three-phase current response to the alternating voltage excitation of the electric machine 2 is carried out for the first modified value d_est−45° into a first alternating current component i_[d_est−45°], and the conversion of the three-phase current response to the alternating voltage excitation of the electric machine is carried out for the second modified value d_est+45° into a second alternating current component i_[d_est+45°].

These two alternating current components are shown in the parts a) to c) of FIG. 1. Now the calculation of the length of a first alternating current vector having d- and q-components for the first alternating current component i_[d_est−45°] is carried out, as well as the calculation of the length of a second alternating current vector having d- and q-components for the second alternating current component i_[d_est+45°].

FIG. 1 schematically shows corresponding ellipses in the real d-q plane. The “estimated” d-axis (d_est) is shown and does not coincide with the direction of the d-axis of the d-q plane here. The alternating current components) i_(d_est+45°) and i_(d_est−45°) are plotted to match the estimated direction of the d-axis.

Then the difference in the absolute values of the lengths between the first alternating current vector and the second alternating current vector is determined according to delta_i=|i_d_est+45°|−|i_d_est−45°|.

If the condition is met that the difference in the absolute values of the lengths between the first alternating current vector and the second alternating current vector is |delta_i|>FTW, which can be seen in parts a) and b) of FIG. 1, a distinction is made between two further alternatives.

For the first case in which |i_d_est+45°|>|i_d_est−45°|, the starting value d_est is adjusted in such a way that the angle representing the rotor position is rotated clockwise by a predetermined absolute value, which is shown in parts a) and b).

From parts a) and b) in FIG. 1 it is clearly visible that the lengths of the alternating current components are different. Therefore, the “estimated” d-axis (d_est) must be rotated clockwise a short way. This new “estimated” d-direction is then the new starting value for the next iteration. One of the next iterations is shown in part b) of FIG. 1.

For the second case in which |i_d_est+45°|<|i_d_est−45°|, an adjustment of the starting value d_est is made in such a way that the angle representing the rotor position is rotated counterclockwise by a predetermined absolute value, which is not shown in FIG. 1, however.

These iterations are carried out until the condition is met that the difference in the absolute values of the lengths between the first alternating current vector and the second alternating current vector is within a defined interval between 0 and a defined error tolerance value FTW, according to |delta_i|<FTW.

In other words, the process is repeated until the projections of the alternating current components and thus the lengths of the absolute values of the alternating current components are equal. The initial angle of the rotor position can then be easily ascertained from the angle of the “estimated” d-axis. This can be seen in part c) of FIG. 1. Then, on this basis, the initial rotor angle is provided to energize the electric machine and the method is terminated.

At the same time, the second application is executed, the steps of which are similar to the sequence of the first application. However, the difference remains that there is a sign reversal in the angle correction of the second application as well as a significant difference between the frequency of the first injection signal and the frequency of the second injection signal.

The descriptions of Figures a) to c) of FIG. 2 correspond to the descriptions of Figures a) to c) of FIG. 1, but taking into account the differences stated above.

After the first and second applications have been completed, the absolute value of the angle difference between the longer semi-axis d and the shorter semi-axis q is determined according to delta_w=|w_d_est−w_q_est|.

When evaluating the angle difference, a distinction is made between two cases:
1. Case: If the condition is met that the angle difference between the absolute values of the longer semi-axis d and the shorter semi-axis q is within a defined interval between 0 and a defined error tolerance value FTW, according to |delta_w−90|≤FTW, energizing the electric machine and terminating the method.
2. If the condition is met that the difference in the absolute values of the lengths between the first alternating current vector and the second alternating current vector is |delta_w−90|>FTW, outputting of a warning message and/or switching off the system.

The method is then repeated at a predefined interval during operation of the electric machine 2 so that continuous anisotropy testing is ensured during operation.

As shown in FIG. 3, the control unit 3 for controlling and energizing the electric machine 2 comprises a processor 4 and a memory 5 containing a computer program code, wherein the memory 5 and the computer program code are configured, with the processor 4, to cause the control unit 3 to carry out the above method.

Unlike what is shown in FIG. 3, the control unit 3 preferably does not have a connection for a rotor position sensor 6 for detecting the rotor position of the rotor 1, and can be controlled without a sensor. The electric machine 2 shown in FIG. 2 has a stator 7 that can be energized and a rotor 1 that can be rotated relative to the stator 7, as well as the control unit 3 for controlling and energizing the electric machine 2 or the stator 7.

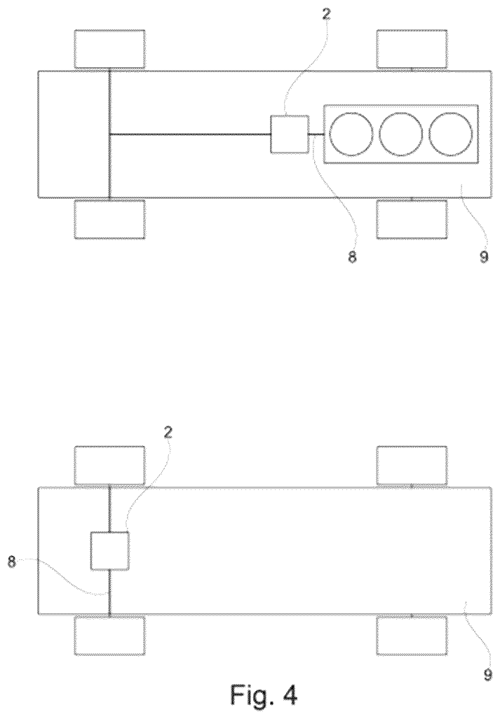

In particular, the electric machine 2 is intended for use in a hybrid or fully electrically operable drive train 8 of a motor vehicle 9, as also outlined in FIG. 4.

The disclosure is not limited to the embodiments shown in the figures. The above description is therefore not to be regarded as limiting, but rather as illustrative. The following claims are to be understood as meaning that a stated feature is present in at least one embodiment of the disclosure. This does not exclude the presence of further features. Where the claims and the above description define ‘first’ and ‘second’ features, this designation serves to distinguish between two features of the same type without defining an order of precedence.

### LIST OF REFERENCE SYMBOLS

1 Rotor
2 Electric machine
3 Control unit
4 Processor
5 Memory
6 Rotor position sensor
7 Stator
8 Drive train
9 Motor vehicle

1. A method for continuous anisotropy testing of an electric machine comprising:
providing an electric machine having a stationary rotor;
executing a first application for determining the angle wdest of a longer semi-axis d of an ellipse using a first injection signal;
executing a second application for determining the angle wqest of a shorter semi-axis q of the ellipse using a second injection signal;
determining the angle difference between the absolute values of the longer semi-axis d and the shorter semi-axis q according to deltaw=|wdest−wq_est|;
when the angle difference between the absolute values of the longer semi-axis d and the shorter semi-axis q is within a defined interval between 0 and a defined error tolerance value FTW, according to |delta_w−90|≤FTW, energizing the electric machine and terminating the method; and
when the difference in the absolute values of the lengths between the first alternating current vector and the second alternating current vector is |delta_w−90|>FTW, outputting a warning message and/or switching off the system.

2. The method according to claim 1, wherein the first application for determining the angle of the longer semi-axis d comprises the following steps:
providing a starting value d_est, which represents a first angle of the rotor position,
generating a three-phase alternating voltage excitation in the electric machine by specifying an alternating voltage in a d_est direction,
converting the three-phase current response to the alternating voltage excitation of the electric machine for the first modified value dest−45° into a first alternating current component i[d_est−45°],
converting the three-phase current response to the alternating voltage excitation of the electric machine for the second modified value dest+45° into a second alternating current component i[d_est+45°],
calculating the length of a first alternating current vector having d and q components for the first alternating current component i[dest−45°],
calculating the length of a second alternating current vector having d and q components for the second alternating current component i[dest+45°],
determining the difference in the absolute values of the lengths between the first alternating current vector and the second alternating current vector according to deltai=|idest+45°|−|id_est−45°|,
when the difference in the absolute values of the lengths between the first alternating current vector and the second alternating current vector is within a defined interval between 0 and a defined error tolerance value FTW, according to |delta_i|≤FTW, providing the initial rotor angle for energizing the electric machine and terminating the method,
when the difference in the absolute values of the lengths between the first alternating current vector and the second alternating current vector is |delta_i|>FTW,
when |idest+45°|>|idest−45°|, adjusting the starting value d_est in such a way that the angle representing the rotor position is rotated clockwise by a predetermined absolute value and
when |idest+45°|<|idest−45°|, adjusting the starting value d_est such that the angle representing the rotor position is rotated counter-clockwise by a predetermined absolute value.

3. The method according to claim 2, wherein the starting value d_est is selected at random when the method is executed for the first time.

4. The method according to claim 2, wherein the second application for determining the angle of the shorter semi-axis q includes a sign reversal in the angle correction.

5. The method according to claim 1, wherein the frequency of the first injection signal and the frequency of the second injection signal are different.

6. A computer program product stored on a machine-readable medium with program code suitable for carrying out the method according to claim 1.

7. A control unit for controlling and energizing an electric machine comprising a processor and a memory containing a computer program code, wherein the memory and the computer program code are configured, with the processor, to cause the control unit to carry out a method according to claim 1.

8. The control unit according to claim 7, wherein the control unit has no connection for a rotor position sensor for detecting the rotor position of a rotor.

9. An electric machine comprising:
a stator;
a rotor rotatable relative to the stator; and
a control unit for controlling and energizing the electric machine, wherein the control unit comprises a processor and a memory containing computer program code, wherein the memory and the computer program code are configured, with the processor, to cause the control unit to:
execute a first application for determining the angle of a longer semi-axis d of an ellipse using a first injection signal;
execute a second application for determining the angle of a shorter semi-axis q of the ellipse using a second injection signal;
determine the angle difference between the absolute values of the longer semi-axis d and the shorter semi-axis q;
when the angle difference between the absolute values of the longer semi-axis d and the shorter semi-axis q is within a defined interval, energizing the electric machine; and
when the difference in the absolute values of the lengths between the first alternating current vector and the second alternating current vector satisfies a selected condition, outputting a warning message and/or switching off the system.

10. The electric machine according to claim 9, wherein the electric machine does not have a rotor position sensor for detecting the rotor position of the rotor.

11. The electric machine according to claim 9, wherein the first application for determining the angle of the longer semi-axis d comprises:
providing a starting value which represents a first angle of the rotor position;
generating a three-phase alternating voltage excitation in the electric machine by specifying an alternating voltage in a d_est direction;
converting the three-phase current response to the alternating voltage excitation of the electric machine for a first modified value dest−45° into a first alternating current component i[d_est−45°];
converting the three-phase current response to the alternating voltage excitation of the electric machine for the second modified value dest+45° into a second alternating current component i[d_est+45°];
calculating the length of a first alternating current vector having d and q components for the first alternating current component i[dest−45°];
calculating the length of a second alternating current vector having d and q components for the second alternating current component i[dest+45°];
determining the difference in the absolute values of the lengths between the first alternating current vector and the second alternating current vector according to deltai=|idest+45°|−|id_est−45°|;
when the difference in the absolute values of the lengths between the first alternating current vector and the second alternating current vector is within a defined interval between 0 and a defined error tolerance value FTW, according to |delta_i|≤FTW, providing the initial rotor angle for energizing the electric machine and terminating the method;
when the difference in the absolute values of the lengths between the first alternating current vector and the second alternating current vector is |delta_i|>FTW,
when |idest+45°|>|idest−45°|, adjusting the starting value d_est in such a way that the angle representing the rotor position is rotated clockwise by a predetermined absolute value; and
when |idest+45°|<|idest−45°|, adjusting the starting value d_est such that the angle representing the rotor position is rotated counter-clockwise by a predetermined absolute value.

12. The electric machine according to claim 11, wherein the starting value d_est is selected at random when the method is executed for the first time.

13. The electric machine according to claim 11, wherein the second application for determining the angle of the shorter semi-axis q includes a sign reversal in the angle correction.

14. The electric machine according to claim 11, wherein the frequency of the first injection signal and the frequency of the second injection signal are different.

15. The electric machine according to claim 11, wherein the electric machine comprises a permanent magnet synchronous machine.

16. A method for continuous anisotropy testing of an electric machine comprising:
providing an electric machine having a stationary rotor;
executing a first application for determining the angle of a longer semi-axis of an ellipse using a first injection signal;
executing a second application for determining the angle of a shorter semi-axis of the ellipse using a second injection signal;
determining the angle difference between the longer semi-axis and the shorter semi-axis;
when the angle difference between the longer semi-axis and the shorter semi-axis is within a defined interval between 0 and a defined error tolerance value, energizing the electric machine and terminating the method;
when the difference in the lengths between a first alternating current vector and a second alternating current vector is greater than a defined tolerance level, performing a mitigation procedure.

17. The method of claim 16, wherein the mitigation action comprises at least one of a warning message or switching off the electric machine.

18. The method according to claim 16, wherein the electric machine comprises a permanent magnet synchronous machine.
